(19) United States
(12) Patent Application Publication
(10) Pub. No.: US 2013/0033822 A1
(43) Pub. Date: Feb. 7, 2013

(54) IMAGE ACQUISITION APPARATUS AND IMAGE ACQUISITION SYSTEM

(71) Applicants: Tomofumi Nishikawara, Utsunomiya-shi (JP); Yukio Tokuda, Kawasaki-shi (JP); Hisashi Namba, Utsunomiya-shi (JP)

(72) Inventors: Tomofumi Nishikawara, Utsunomiya-shi (JP); Yukio Tokuda, Kawasaki-shi (JP); Hisashi Namba, Utsunomiya-shi (JP)

(73) Assignee: CANON KABUSHIKI KAISHA, Tokyo (JP)

(21) Appl. No.: 13/563,538

(22) Filed: Jul. 31, 2012

(30) Foreign Application Priority Data
Aug. 3, 2011 (JP) 2011-170289

(51) Int. Cl. H05K 7/20; H05B 1/00; F25B 21/02

(52) U.S. Cl. 361/704; 62/3.2; 219/482

(57) ABSTRACT

An image acquisition apparatus includes an imaging optical system configured to form an image of a subject, an imaging unit including an image sensor configured to capture the image of the subject formed by the imaging optical system, a cooler thermally connected to the image sensor, and a heat-transfer reduction unit with an opaque portion located between the imaging optical system and the imaging unit, wherein the opaque portion includes an aperture through which incident light to the image sensor passes.

### BACKGROUND OF THE INVENTION

1. Field of the Invention

The present invention relates to an image acquisition apparatus and an image acquisition system.

2. Description of the Related Art

In the field of pathology or the like, an image acquisition system has become a focus of attention. The image acquisition system includes an image acquisition apparatus (for example, a microscope) and a display apparatus. The image acquisition apparatus captures an image of a subject, whereby it is possible to acquire a digital image and to display the digital image on the display apparatus in high resolution.

In an image acquisition apparatus, there is a requirement for capturing a subject in high resolution and at high speed. For this purpose, it is necessary to capture an image of as wide an area as possible of the subject in high resolution at a time. In view of this, there has been proposed in Japanese Patent Application Laid-Open No. 2009-003016 an image acquisition apparatus which uses an objective lens of wide field of view and high resolution and in which an image sensor group is arranged within the field of view.

With an increase in temperature, the image sensor is affected by a noise due to dark current, and the image acquired tends to deteriorate. Thus, to acquire a high quality image, it is important to cool the image sensor when using it. To cool the image sensor, a method is known according to which a thermoelectric element is arranged on the back surface of the image sensor (the surface on the side opposite the imaging surface). For example, when a Peltier element is employed as the thermoelectric element, it is possible to cool the image sensor down to 0° C. or below. On the other hand, an optical element such as an objective lens is designed in conformity with the temperature of the environment in which image acquisition is conducted (assuming, for example, a case where room temperature is approximately 20° C.). When being brought close to each other, two members of different temperatures affect each other due to heat transfer. Thus, when the image sensor and the optical element are close to each other, the temperature of the optical element decreases greatly as compared with the design value, with the result that the optical performance of the optical element deteriorates, making it impossible to acquire an image of high resolution.

Japanese Patent No. 03096038 proposes a construction in which, when a subject on a heat generation plate is observed in a high temperature condition, a protector forming an airflow is arranged between the objective lens and the heat generation plate so that the heat of the heat generation plate may not be transferred to the objective lens.

However, transparent glass is used for the protector discussed in Japanese Patent No. 03096038, so that it is impossible to suppress heat transfer due to radiation. Further, since it is necessary to cause a large amount of air to flow in order to attain a heat insulation effect, the flow path diameter cannot but be rather large, making it impossible to bring the objective lens and the subject close to each other. Thus, it is rather difficult to arrange the protector as discussed in Japanese Patent No. 03096038 in an image acquisition apparatus in which the image sensor and the objective lens are close to each other.

### SUMMARY OF THE INVENTION

An aspect of the present invention is directed to an image acquisition apparatus including an image sensor and an optical element close to each other, wherein the influence due to heat transfer, such as radiation between the image sensor and the optical element, is suppressed, making it possible to acquire an image of high resolution.

According to an aspect of the present invention, an image acquisition apparatus includes an imaging optical system configured to form an image of a subject, an imaging unit including an image sensor configured to capture the image of the subject formed by the imaging optical system, a cooler thermally connected to the image sensor, and a heat-transfer reduction unit including an opaque portion located between the imaging optical system and the imaging unit, wherein the opaque portion includes an aperture through which incident light to the image sensor passes.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 illustrates the system configuration of an image acquisition system according to a first exemplary embodiment of the present invention.

FIGS. 2A and 2B are a top view and a sectional view of a prepared slide, respectively.

FIG. 3 is a sectional view of an objective lens.

FIG. 4 is a top view of an imaging unit.

FIGS. 5A and 5B are a schematic sectional view of the portion around the imaging unit and a plan view of a heat-transfer reduction unit, respectively, according to the first exemplary embodiment.

FIGS. 6A and 6B are a schematic sectional view of the portion around an imaging unit and a plan view of a heat-transfer reduction unit, respectively, according to a second exemplary embodiment of the present invention.

FIGS. 7A and 7B are a schematic sectional view of the portion around an imaging unit and a plan view of a heat-transfer reduction unit, respectively, according to a third exemplary embodiment of the present invention.

### DESCRIPTION OF THE EMBODIMENTS

Various exemplary embodiments, features, and aspects of the invention will be described in detail below with reference to the drawings.

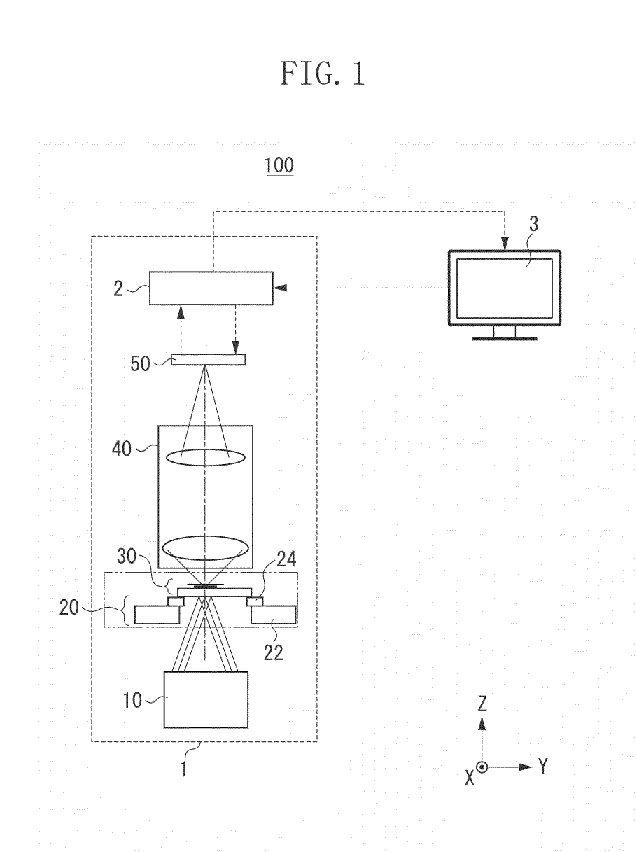

FIG. 1 is a diagram illustrating the system configuration of an image acquisition system 100 according to the first exemplary embodiment of the present invention. The image acquisition system 100 is a system for acquiring an image of a subject (prepared slide) and displaying the image.

The image acquisition system includes a microscope 1 as an image acquisition apparatus for capturing an image of a prepared slide 30, and a display device 3 for displaying a digital image acquired by the microscope 1.

First, the microscope 1 will be described.

The microscope 1 has an illumination unit 10 for illuminating the prepared slide 30, an objective lens 40 for performing image formation of the prepared slide 30, and an imaging unit 50 for capturing an image of the prepared slide 30. A stage 20 is a member for retaining and moving the prepared slide 30.

The illumination unit 10 includes a light source unit (not illustrated), and an illumination optical system (not illustrated) for guiding the light from the light source unit to the prepared slide 30. As a light source of the light source unit, it is possible to employ a white light source, a light-emitting diode (LED) light source, or the like. The light source of the present exemplary embodiment is equipped with a light-emitting diode (LED) having the wavelength of each of the colors, red, green, and blue (RGB) . In the case where a white light source is implemented, it is possible to generate light of the wavelength of each of the colors RGB through a combination with a color filter.

The stage 20 includes a retaining unit (not illustrated) retaining the prepared slide 30, an XY-stage 22 configured to move the retaining unit in the XY-directions, and a Z-stage 24 configured to move the retaining unit in the Z-direction. The Z-direction corresponds to the optical axis direction of the objective lens 40, and the XY-directions correspond to directions perpendicular to the optical axis. The XY-stage 22 and the Z-stage 24 are provided with apertures allowing passage of the light from the illumination unit 10.

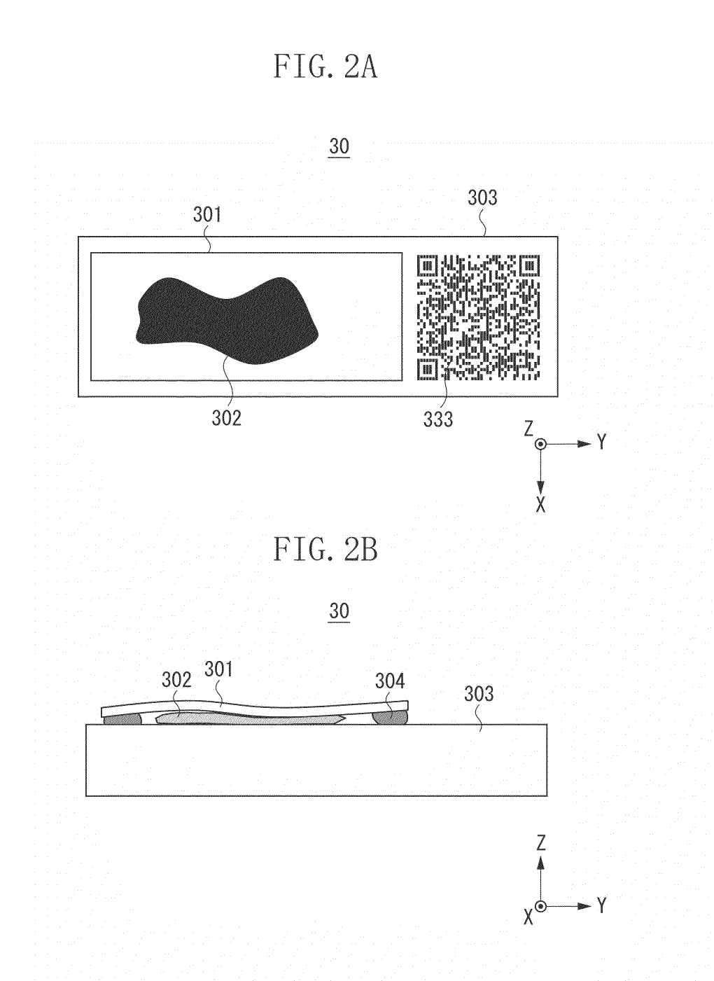

FIGS. 2A and 2B are a top view and a sectional view of the prepared slide 30, respectively. As illustrated in FIGS. 2A and 2B, the prepared slide 30, which is an example of the subject, is composed of a cover glass 301, a sample 302, and a slide glass 303. The sample 302 (e.g., a living body sample like a slice of tissue) arranged on the slide glass 303 is sealed by the cover glass 301 and adhesive 304. A label (barcode) 333, on which the requisite information for controlling the prepared slide 30 (the sample 302), such as the identification number of the slide glass and the thickness of the cover glass, is recorded and may be attached to the slide glass 303. While in the present exemplary embodiment the object of image acquisition is the prepared slide 30 as the subject, the subject may also be, for example, a substrate or the like to be subjected to external inspection (inspection for adhesion of foreign matter, flaws, etc.).

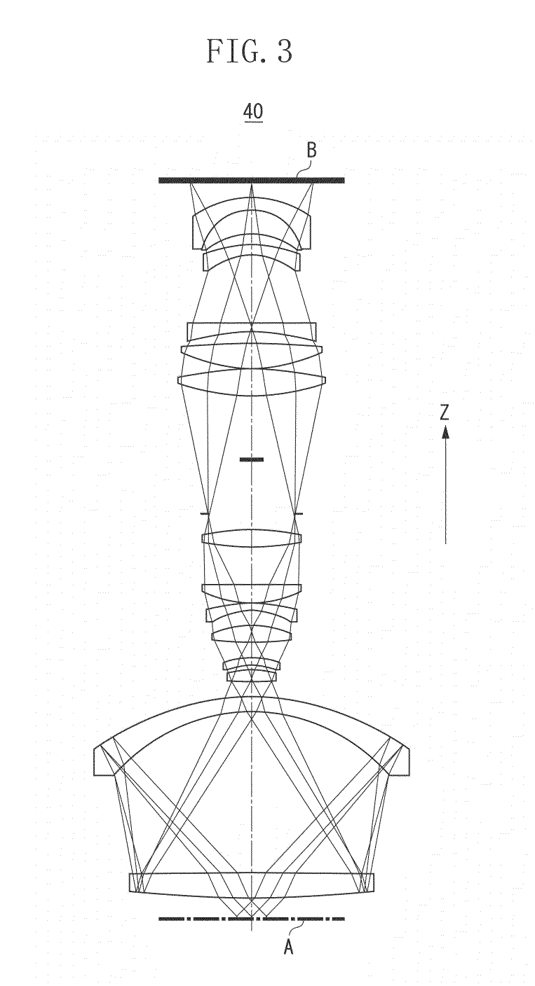

FIG. 3 is a sectional view of the objective lens 40. The objective lens 40 is an imaging optical system for performing image formation on the imaging surface of the imaging unit 50 with the prepared slide 30 enlarged at a predetermined magnification. More specifically, as illustrated in FIG. 3, the objective lens 40 includes lenses and a mirror, and is configured to perform image formation on an imaging surface B with an image on an object surface A. In the present exemplary embodiment, the objective lens 40 is arranged such that the prepared slide 30 and the imaging surface of the imaging unit 50 are optically conjugate to each other. The object on the object surface A corresponds to the prepared slide 30, and the imaging surface B corresponds to the surface of an imaging area 555 (illustrated in detail below) of the imaging unit 50. The numerical aperture (NA) on the object surface side of the object lens 40 is typically 0.7 or more. Further, the objective lens 40 is typically formed so as to be capable of performing image formation at one time at least over an area of 10 mm×10 mm on the object surface. The objective lens 40 is designed taking into account the temperature of the environment where the image acquisition is to be performed. For example, when the average ambient temperature is 20° C., the objective lens is designed using the value of 20° C. as a reference. In this case, the temperature of the objective lens 40 guaranteeing the requisite optical performance ranges from approximately 10° C. to 30° C., which is the range in which image acquisition is performed.

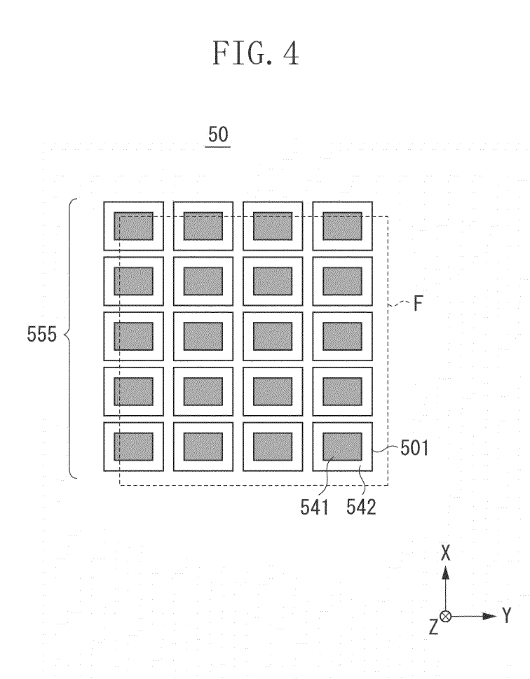

FIG. 4 is a top view of the imaging unit 50. As illustrated in FIG. 4, the imaging unit 50 includes the imaging area 555, which is composed of a plurality of two-dimensionally arranged image sensors 501, thus enabling capturing an image of a region F of the image plane of the objective lens 40 at one time. The imaging surface B illustrated in FIG. 3 is formed by the imaging area 555. Charge-coupled devices (CCDs), complementary metal oxide semiconductor (CMOS) sensors, or the like can be used as the image sensors 501. The number of image sensors mounted on the imaging unit 50 is determined based on the area of the image plane of the objective lens 40. For example, it is possible to adopt a construction where only one image sensor is arranged. The number of image sensors is determined based on the configuration of the image plane of the objective lens 40, the configuration and construction of the image sensors, etc. In the present exemplary embodiment, the imaging area 555 is implemented such that 5×4 CMOS sensors are arranged in the X-Y directions. In the imaging unit 50, there exists a base surface 542 around an imaging region 541 of each of the plurality of image sensors 501. Thus, in the image acquired through one shooting by the imaging unit 50, the portion corresponding to the gap between the imaging regions 541 is left out. In view of this, in the image acquisition apparatus according to the present exemplary embodiment, to fill up the gap between the imaging regions 541, the stage 20 is moved, and imaging is performed a plurality of times while changing the positional relationship between the prepared slide 30 and the imaging area 555, whereby it is possible to acquire an image of the sample 302 free from dropouts. By performing this operation at high speed, it is possible to capture an image of a wide area while shortening the requisite time for imaging. The imaging unit 50 is retained by a main body frame (not illustrated) or the lens barrel (not illustrated) of the objective lens 40.

Referring back to FIG. 1, a control device 2 is includes a computer including a central processing unit (CPU), memory, a hard disk, etc. The control device 2 performs imaging control, and processes the image data of the captured prepared slide 30, thereby preparing a digital image. More specifically, the control device 2 performs position matching between the images captured a plurality of times while moving the stage 20 in the XY-directions, and connects the images together, thereby preparing an image of the sample 302 free from gaps. Further, in the image acquisition apparatus according to the present exemplary embodiment, an image of the sample 302 is captured for each of the colors RGB of the light from the light source unit, so that by the control device 2 combining the data on those images, a color image of the sample 302 is generated.

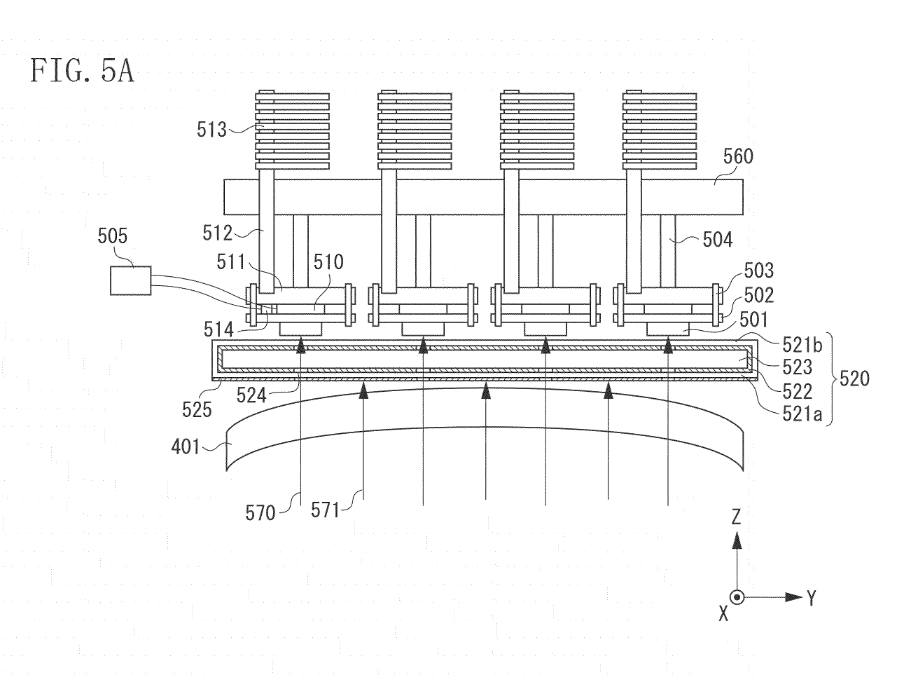

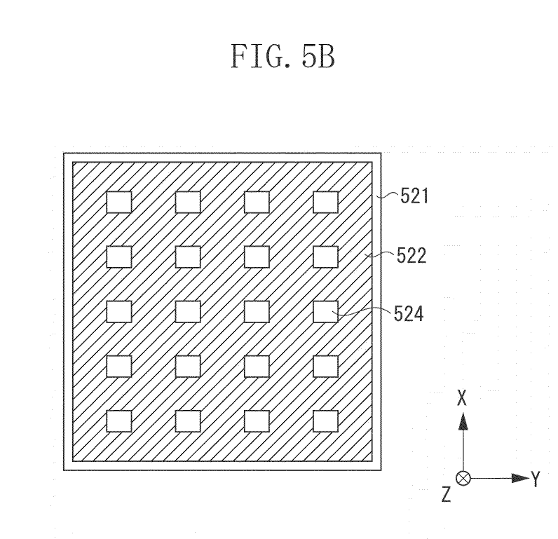

Next, a cooler for the image sensors 501 will be described. In the image acquisition apparatus according to the present exemplary embodiment, a thermoelectric element is used as the cooler. By cooling the image sensors 501 using a thermoelectric element, it is possible to acquire a high quality image in which noise due to dark current is reduced. The cooling process is described in more detail below with reference to FIGS. 5A and 5B.

FIGS. 5A and 5B are a schematic sectional view of the portion around the imaging unit 50 and a plan view of the heat-transfer reduction unit, respectively, in the microscope 1 according to the present exemplary embodiment. The image sensors 501 are thermally connected to Peltier elements 510 serving as the thermoelectric elements via substrates 502, and are cooled by the Peltier elements 510. Each Peltier element 510 is held between the substrate 502 and a metal block 511 of high heat conductivity (e.g., copper, aluminum, or heat pipe), and is firmly fixed in position by a fixation member 503, e.g., a screw. The low temperature side of each Peltier element 510 is attached to the substrate 502, and the high temperature side thereof is attached to the metal block 511. A heat conductive sheet or a heat conductive grease is provided or applied between the contact surfaces of the Peltier element 510 and of the substrate 502 and between the contact surfaces of the Peltier element 510 and of the metal block 511. A retaining portion 504 connects each metal block 511 and a surface plate 560 to retain the image sensors 501. Heat pipes 512 are provided between the metal blocks 511 and radiation fins 513, transporting the heat generated in the image sensors 501 and the Peltier elements 510 to the radiation fins 513 to dissipate the heat. The cooling method for the radiation fins 513 is selected as appropriate from a natural convection system, a forcible convection system using a blower, and a water cooling system according to the conditions such as the quantity of heat to be dissipated, temperature, and design space.

Here, of the lenses constituting the objective lens 40, a lens 401 closest to the image sensors 501 is provided with a temperature sensor 514. Further, a control unit 505 is electrically connected to the Peltier elements 510 and the temperature sensor 514. The control unit 505 controls the value of an electric current applied to the Peltier elements 510 based on temperature information from the temperature sensor 514, whereby control is effected such that the image sensors 501 attain a desired control temperature T1. The control temperature T1 is a value determined as appropriate according to the specifications of the image sensors 501. In the present exemplary embodiment, it is approximately 5° C. An optical bench 560 is retained by a main body frame (not illustrated) or the lens barrel (not illustrated) of the objective lens 40. Although in the present exemplary embodiment the Peltier elements 510 are used as the cooler for the image sensors 501, it is also possible to form a cooler by a heat sink or a fin, and arrange this cooler on the substrate 502 to effect water cooling or air cooling. On the other hand, the objective lens 40 undergoes optical design at the temperature T2 (which, in the present exemplary embodiment, is approximately 20° C.) of the environment where image acquisition is performed. Thus, in the case where the image sensors 501 and the objective lens 40 are close to each other, the temperature of the objective lens 40 decreases, and the optical performance deteriorates due to thermal strain and a change in refractive index. In view of this, in the present exemplary embodiment, in order that incident light 570 to the image sensors 501 may not be intercepted, a heat-transfer reduction unit is arranged between the image sensors 501 and the objective lens 40. As a result, the heat transfer between the image sensors 501 and the objective lens 40 is reduced, so that they can respectively be controlled to the desired temperatures T1 and T2, making it possible to acquire an image of high quality.

In the following, the heat-transfer reduction unit according to the present exemplary embodiment will be described more specifically with reference to FIGS. 5A and 5B. The present exemplary embodiment employs, as the heat-transfer reduction unit, a vacuum heat insulation member 520 having a reflection film 522 constituting an opaque portion, whereby it is possible to suppress radiation and other forms of heat transfer. The vacuum heat insulation member 520 is arranged between the image sensors 501 and the lens 401. The vacuum heat insulation member 520 forms inside a container a substantially vacuum closed space 523. By adopting transparent flat glasses 521a and 521b (having a thickness of several mm or less) as the material of the container, it is possible to allow transmission of the incident light to the image sensors 501. In the case of a vacuum, no heat conduction or convection is generated, so that it is possible to prevent heat transfer by such phenomenon. Further, there is no lower limit to the size in the thickness direction of the closed space 523, so that the thickness of the vacuum heat insulation member 520 is determined by restrictions such as the machining of the flat glasses 521a and 521b and the strength thereof. Accordingly, the vacuum heat insulation member 520 according to the present exemplary embodiment is more advantageous than a heat insulation member of the type in which fluid (such as air or water) is caused to flow between the flat glasses 521a and 521b in that it allows a reduction in thickness.

Also in the case of a vacuum, heat transfer due to radiation occurs. Thus, even when the vacuum heat insulation member 520 is arranged, heat transfer is allowed to occur between the image sensors 501 and the lens 401 in close proximity thereto. In view of this, in the present exemplary embodiment, the reflection film 522 is formed on the vacuum insulation member 520 as the opaque portion, thereby suppressing heat transfer due to radiation. The reflection film 522 is formed on the surface of the flat glasses 521a and 521b except for the passage region where the incident light to the image sensors 501 is allowed to pass. Thus, the reflection film 522 is provided with an aperture 524 allowing transmission of the incident light to the image sensors 501. As the material of the reflection film 522, there is adopted an opaque material whose emissivity (radiation factor) is low (0.5 or less), so that it is possible to suppress heat transfer due to radiation by the reflection film 522, making it possible to reduce the quantity of heat flowing from the flat glass 521a to the flat glass 521b.

Further, on the lower surface of the flat glass 521a, there is formed a light absorption film 525 with high emissivity (0.5 or more) except for the passage region allowing passage of the incident light to the image sensors 501. Accordingly, the portion of the incident light 571 which does not undergo image formation on the image sensors 501 is reflected by the reflection film 522, making it possible to prevent it from entering the image sensors 501. The portion where the light absorption film 525 is formed is not restricted to the lower surface of the flat glass 521a. It may also be formed on the upper surface or side surfaces of the flat glass 521b.

In the image acquisition apparatus according to the present exemplary embodiment described above, the vacuum heat insulation member 520 is provided, whereby it is possible to suppress heat transfer between the image sensors 501 and the lens 401 in close proximity to each other, and to control each of them to a desired temperature. In particular, the heat-transfer reduction unit according to the present exemplary embodiment has the reflection film 522 provided with the aperture 524 allowing passage of the incident light to the image sensors 501, whereby it is possible to suppress heat transfer due to radiation, making it possible to acquire an image of high quality.

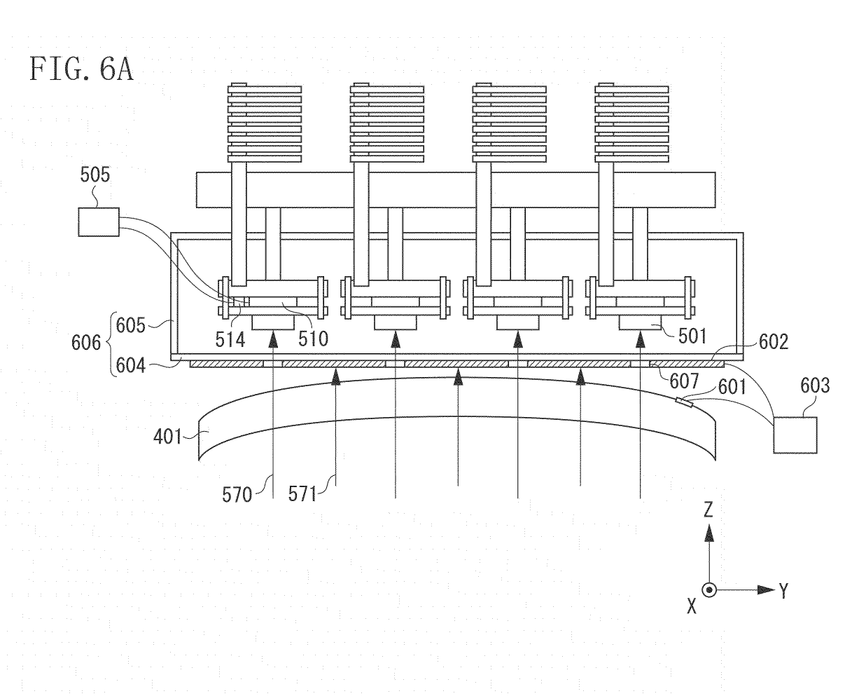

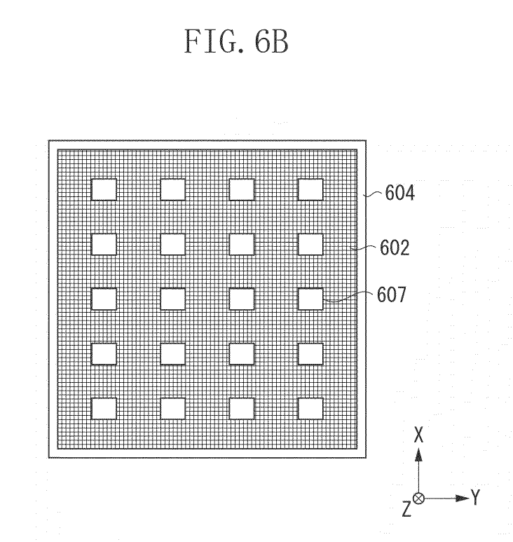

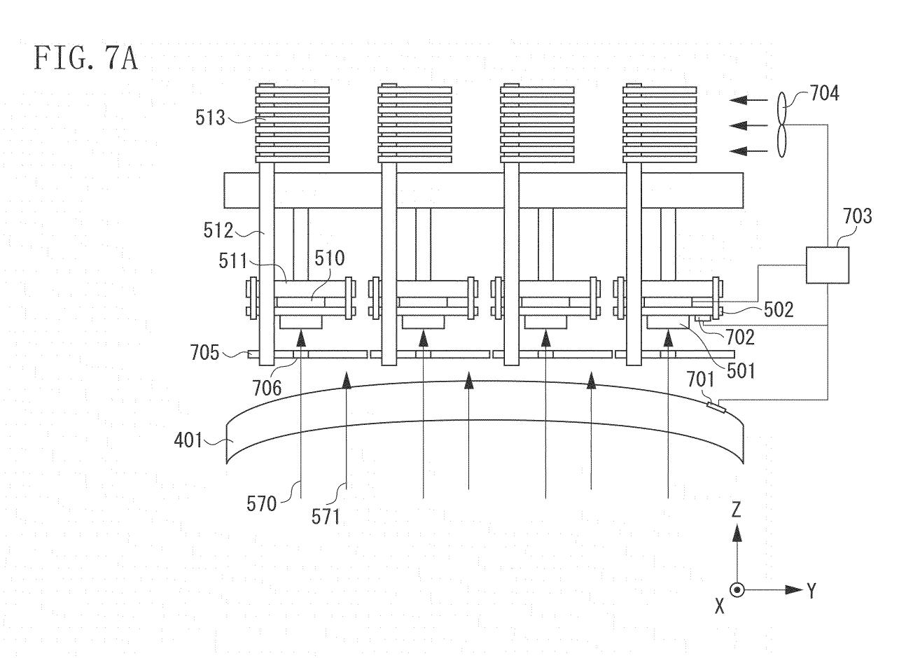

In the following, a second exemplary embodiment of the present invention will be described with reference to FIGS. 6A and 6B. In the following description, the components that are similar to or equivalent to those of the above-illustrated exemplary embodiment are denoted by the same reference numerals, and a description thereof will be abridged or left out. FIGS. 6A and 6B are a schematic sectional view of a portion around the imaging unit 50 and a plan view of a heat-transfer reduction unit, respectively, in the microscope 1 according to the present exemplary embodiment. The heat-transfer reduction unit according to the present exemplary embodiment has a heat generating heater 602, which is an opaque portion, a temperature sensor 601 provided on the lens 401, and a heater control unit 603 electrically connected to the heat generating heater 602 and the temperature sensor 601. As the heat generating heater 602, it is possible to adopt a thin heater composed of a conductive plate, a conductive film, a conductor or the like. The heat generating heater 602 is arranged so as to cover an area except for the passage region where the incident light to the image sensors 501 is allowed to pass. More specifically, the heat generating heater 602 is provided with an aperture 607 allowing passage of the incident light to the image sensors 501, and is arranged on the lower surface of a transparent flat glass plate 604 (several mm thick) . Here, the heat generating heater 602 is formed of an opaque member such as a conductive plate, so that it is possible to suppress heat transfer through radiation between the image sensors 501 and the lens 401 in close proximity thereto.

Further, by controlling the electric power applied to the heat generating heater 602 by the heater control unit 603, it is possible to control the temperature of the heat generating heater 602. Thus, by controlling the temperature of the heat generating heater 602 based on temperature information from the temperature sensor 601, it is possible to maintain the temperature of the lens 401 at the temperature T2 at which the requisite optical performance is guaranteed, so that it is possible to suppress a reduction in the temperature of the lens 401 due to heat transfer and convection. As in the case of the first exemplary embodiment, the image sensors 501 are controlled to the desired temperature T1 by using the Peltier elements 510.

In the case where the control temperature T1 of the image sensors 501 is lower than the control temperature T2 of the lens 401, there is a fear of generation of dew condensation at the image sensors 501. In the present exemplary embodiment, however, a case 606 formed by the flat glass plate 604 and a wall surface 605 surrounds the image sensors 501 and the Peltier elements 510, and dry air 608 (air whose dew point is lower than the temperature T1) is sealed within the case 606. Accordingly, even if the control temperature T1 of the image sensors 501 is lower than the dew point of the ambient air, there is no fear of generation of dew condensation. In the case where there is no fear of dew condensation on the image sensors 501, that is, in the case where the dew point of the ambient air around the image sensors 501 is lower than the control temperature T1, the case 606 may be removed. Further, to suppress reflection of the portion of the incident light 571 which does not undergo image formation at the image sensors 501, a light absorption film may be formed on the surface of the heat generating heater 602.

In the image acquisition apparatus according to the present exemplary embodiment described above, it is possible to suppress the influence of heat transfer between the image sensors 501 and the lens 401 in close proximity thereto due to the heat-transfer reduction unit including the heat generating heater 602 provided with the aperture 607 allowing passage of the incident light to the image sensors 501. Thus, it is possible to control the image sensors 501 and the lens 401 in close proximity thereto respectively to desired temperatures, so that it is possible to acquire an image of high quality.

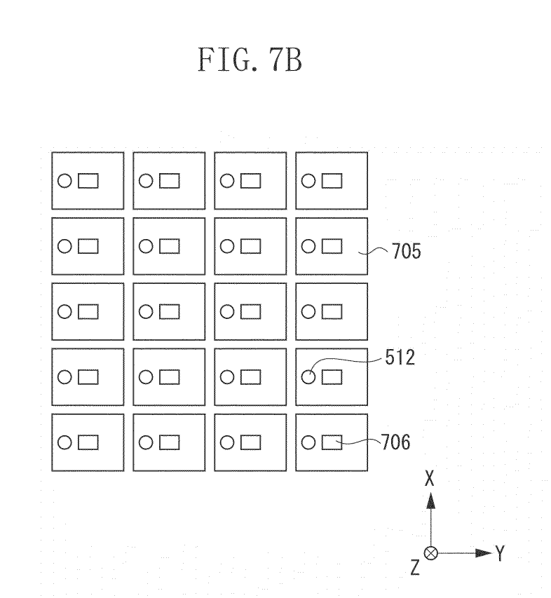

In the following, a third exemplary embodiment of the present invention will be described with reference to FIGS. 7A and 7B. In the following description, the components which are similar to or equivalent to those of the above-described exemplary embodiments are denoted by the same reference numerals, and a description thereof will be abridged or left out. FIGS. 7A and 7B are a schematic sectional view of a portion around the imaging unit 50 and a plan view of the heat-transfer reduction unit, respectively, in the microscope 1 according to the present exemplary embodiment. The heat-transfer reduction unit according to the present exemplary embodiment has a copper plate 705, which is an opaque portion, the metal blocks 511, the heat pipes 512, the heat radiation fins 513, temperature sensors 701 and 702, a control unit 703, and a heat radiation blower 704. The copper plate 705 is retained by the heat pipes 512 constituting the heat conduction members between the image sensors 501 and the lens 401, and is provided with an aperture 706 allowing passage of the incident light to the image sensors 501. As a result, it is possible to arrange the copper plate 705 without intercepting the passage region where the incident light to the image sensors 501 passes. On the lower surface of the copper plate 705, there is provided a light absorption film in order to suppress reflection of the portion of the incident light 571 which does not undergo image formation at the image sensors 501. The material of the copper plate 705 is not restricted to copper. The plate may also be some other opaque highly heat conductive member such as an aluminum plate or a heat pipe. With this plate, it is possible to suppress heat transfer through radiation between the image sensors 501 and the lens 401 in close proximity thereto.

The heat radiation blower 704 is a cooling unit configured to promote heat radiation of the heat pipes 512 via the heat radiation fins 513 through forcible convection. The heat radiation fan 704 is electrically connected to the control unit 703, and the rotational frequency (RPM) of the heat radiation blower 704 is controlled by the control unit 703 based on temperature information from the temperature sensors 701 and 702 respectively mounted to the lens 401 and the substrate 502. Although in the present exemplary embodiment an air cooling unit composed of the heat radiation blower 704 is used as the cooling unit, it is also possible to adopt a liquid cooling unit configured to control the flow rate of refrigerant in a circulation pump by the control unit 703. Further, it is also possible to use, together with the cooling unit, a temperature controller. In this case, the blower or the circulation pump cools the heat radiation fins 513 by supplying a temperature-controlled refrigerant (air or liquid) . The heat pipes 512 are connected to the metal blocks 511, which are in contact with the high temperature side of the Peltier elements 510, which means they are thermally connected to the Peltier elements 510. Accordingly, it is possible to transport the heat generated at the image sensors 501 and the Peltier elements 510 to the heat radiation fins 513 by the heat pipes 512, thereby dissipating the heat. In the present exemplary embodiment, the heat pipes 512 pass through the substrate 502 and are thermally connected to the copper plate 705, so that they are thermally separated from the substrate 502. At this time, the temperature of the copper plate 705 is substantially the same as the temperature T3 of the high temperature side of the Peltier elements 510. Thus, the temperature T3 of the copperplate 705 can be controlled by the RPM of the heat radiation blower 704. When the RPM is increased, the temperature T3 is lowered. Thus, the control unit 703 controls the RPM of the heat radiation blower 704 based on the temperature information from the temperature sensor 701, whereby it is possible to control the temperature T3 of the copper plate 705 such that the lens 401 is controlled to the control temperature T2, so that it is possible to suppress a reduction in the temperature of the lens 401 due to heat transfer and convection.

As in the case of the first and second exemplary embodiments, the temperature of the image sensors 501 can be controlled by the value of the electric current applied to the Peltier elements 510. Thus, the control unit 703 controls the current value based on the temperature sensor 702 such that the image sensors 501 are kept at the control temperature T1.

Depending on the conditions such as the control temperatures T1 and T2, there is a fear of generation of dew condensation on the image sensors 501. In this case, as in the case of FIGS. 6A and 6B, it is possible to suppress generation of dew condensation by surrounding the image sensors 501 by a case in which dry air is sealed. In this case, the bottom portion of the case is inserted between the image sensors 501 and the copper plate 705, and transparent glass may be adopted for the region of the case where the incident light 570 to the image sensors 501 passes. Further, at the bottom portion of the case, there are formed openings so that the heat pipes 512 may pass through the same, with the gaps between the case and the heat pipes 512 being sealed by an elastic material.

In the image acquisition apparatus according to the present exemplary embodiment, it is possible to reduce the influence of the heat transfer between the image sensors 501 and the lens 401 in close proximity thereto by the heat-transfer reduction unit including the copper plate 705 provided with the aperture 706 allowing passage of the incident light to the image sensors 501. Accordingly, it is possible to respectively control the image sensors 501 and the lens 401 in close proximity thereto to the desired temperatures, so that it is possible to acquire an image of high quality. Further, the lens 401 is heated by utilizing the heat discharged from the image sensors 501 and the Peltier elements 510, so that it is possible to achieve a reduction in power consumption for the temperature control as compared with the case of a heater.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2011-170289 filed Aug. 3, 2011, which is hereby incorporated by reference herein in its entirety.

What is claimed is:

1. An image acquisition apparatus comprising:
an imaging optical system configured to form an image of a subject;
an imaging unit including an image sensor configured to capture the image of the subject formed by the imaging optical system;
a cooler thermally connected to the image sensor; and
a heat-transfer reduction unit including an opaque portion located between the imaging optical system and the imaging unit,
wherein the opaque portion includes an aperture through which incident light to the image sensor passes.

2. The image acquisition apparatus according to claim 1, further comprising a control unit,
wherein the control unit controls a temperature of the image sensor by controlling an electric current applied to the cooler.

3. The image acquisition apparatus according to claim 2, wherein the cooler includes a thermoelectric element.

4. The image acquisition apparatus according to claim 2, wherein the control unit controls the temperature of the image sensor to be lower than a temperature of the imaging optical system.

5. The image acquisition apparatus according to claim 1, wherein the heat-transfer reduction unit includes a vacuum closed space.

6. The image acquisition apparatus according to claim 1, wherein the opaque portion includes a reflection film with an emissivity less than or equal to 0.5.

7. The image acquisition apparatus according to claim 1, wherein a surface of the heat-transfer reduction unit includes a light absorption film with an emissivity greater than or equal to 0.5, except for a passage region where the incident light to the image sensors passes.

8. The image acquisition apparatus according to claim 1, wherein the opaque portion includes a heater,
wherein the heat-transfer reduction unit includes a heater control unit, and
wherein the heater control unit controls a temperature of the heater by controlling an electric power applied to the heater, and, wherein controlling the temperature of the heater, controls a temperature of the imaging optical system.

9. The image acquisition apparatus according to claim 8, wherein a surface of the heater includes a light absorption film with an emissivity greater than or equal to 0.5.

10. The image acquisition apparatus according to claim 3, wherein the heat-transfer reduction unit includes:
a heat conduction member thermally connected to the opaque portion and the thermoelectric element; and
a cooling unit configured to cool the heat conduction member by supplying a refrigerant thereto,
wherein the control unit controls at least one of a flow rate and a temperature of the refrigerant supplied by the cooling unit,
wherein the cooling unit, by controlling the temperature of the heat conduction member, controls a temperature of the opaque portion, and
wherein, by controlling the temperature of the opaque portion, the cooling unit controls a temperature of the imaging optical system.

11. The image acquisition apparatus according to claim 1, wherein the imaging unit includes a plurality of image sensors.

12. The image acquisition apparatus according to claim 11, wherein the opaque portion includes a plurality of apertures through which the incident light to each of the plurality of image sensors passes.

13. An image acquisition system comprising:
an image acquisition apparatus comprising:
an imaging optical system configured to form an image of a subject;
an imaging unit including an image sensor configured to capture the image of the subject formed by the imaging optical system;
a cooler thermally connected to the image sensor; and
a heat-transfer reduction unit including an opaque portion located between the imaging optical system and the imaging unit,
wherein the opaque portion includes an aperture through which incident light to the image sensor passes; and
a display apparatus configured to display the image of the subject acquired by the image acquisition apparatus.
